(19) United States
(12) Patent Application Publication
(10) Pub. No.: US 2023/0335589 A1
(43) Pub. Date: Oct. 19, 2023

(54) TRANSISTOR AND METHOD FOR FABRICATING THE SAME

(71) Applicant: BEIJING HUA TAN YUAN XIN ELECTRONICS TECHNOLOGY CO., LTD., Beijing (CN)

(72) Inventor: Haitao XU, Beijing (CN)

(73) Assignee: BEIJING HUA TAN YUAN XIN ELECTRONICS TECHNOLOGY CO., LTD., Beijing (CN)

(21) Appl. No.: 18/043,728

(22) PCT Filed: Nov. 13, 2020
(86) PCT No.: PCT/CN2020/128595

§ 371 Date: Mar. 1, 2023

(30) Foreign Application Priority Data
Jul. 31, 2020 (CN) 202010759392.5

(51) Int. Cl. H01L 21/8234; H01L 29/775; H01L 29/06; H01L 29/786; H01L 29/66; H01L 27/088

(52) U.S. Cl. CPC H01L 29/0673; H01L 21/823412; H01L 21/823418; H01L 21/823468; H01L 27/088; H01L 29/66439; H01L 29/6656; H01L 29/775; H01L 29/78681; H01L 29/78696

(57) ABSTRACT

A transistor and a fabrication method thereof are provided. The transistor includes a substrate, a low-dimensional material layer, a gate, a source, a drain, a gate dielectric layer, and spacers. The low-dimensional material layer is provided above the substrate. The source is located at a first side of the gate. The drain is located at a second side of the gate. The gate dielectric layer is provided between the gate and the low-dimensional material layer. The spacers are provided between the source and the gate and between the drain and the gate, respectively. The substrate has fixed charges, or interface dipoles are formed by the substrate and an insulating dielectric layer. The insulating dielectric layer includes at least one of the gate dielectric layer and the spacers. In the transistor, the low-dimensional material layer may be electrostatically doped in various ways, which have low cost and are better compatible with the fabricating process of the transistor.

### CROSS-REFERENCE TO RELATED APPLICATION

This application claims priority to and benefits of Chinese Patent Application Serial No. 202010759392.5, filed with the National Intellectual Property Administration of PRC on Jul. 31, 2020, the entire content of which is incorporated herein by reference.

### FIELD

The present disclosure relates to the field of semiconductor devices, and more particularly to a transistor and a method for fabricating the same.

### BACKGROUND

Low-dimensional semiconductor materials, such as carbon nanotubes, black phosphorus, molybdenum disulfide and the like, are suitable for use in transistors as channel materials due to their excellent properties, such as ultra-thin channel and high mobility. As to traditional silicon-based transistors, p-type and n-type regions may be formed respectively by ion implantation, thereby forming semiconductor devices with various structural functions, such as diodes, field effect transistors, and the like. However, due to the particularity of low-dimensional semiconductor materials, there are various problems in doping the channel materials by traditional thermal diffusion and ion implantation. Therefore, the current transistors with low-dimensional semiconductor materials as channel materials and their fabrication methods still need to be improved.

### SUMMARY

The present disclosure is made based on the inventor’s discovery and understanding of the following problems.

Threshold voltage is a key factor to determine the performance and power consumption of transistors during operation. For traditional silicon-based transistors, the threshold voltage is mainly regulated by controlling ion doping and adjusting gate stacking, which requires complex processes and has low flexibility. Besides, in design and fabrication of chips, because different functional modules have different requirements for drive capability and power consumption, the threshold voltages of the transistors are also different. Furthermore, in silicon-based integrated circuits, the differential regulation of threshold voltages of different functional modules requires complicated designs and processes, and thus the cost is relatively high.

As mentioned above, when low-dimensional semiconductor materials are used as channel materials of transistors, there are various problems in doping the channel materials by traditional thermal diffusion and ion implantation. For example, low-dimensional materials are more susceptible to being affected by the environment than traditional semiconductor materials, so it is difficult to form uniform and reliable doping by thermal diffusion or ion implantation, and it is easy to damage the low-dimensional materials in the doping process. Further, the thickness of channels formed from the low-dimensional materials is extremely thin, usually equal to the thickness of only one or several monoatomic layers, so it is difficult to achieve effective doping in the channels by traditional ion doping processes, and the ions are more likely to be distributed in insulating substrates. Moreover, with respect to some low-dimensional materials (such as carbon nanotubes and graphene) which have stable chemical properties and very strong chemical bond energy among atoms without dangling bonds on their surface, it is difficult to bond doped ions with carbon atoms in the low-dimensional materials to form a stable structure, but the doped ions tend to exist in an unstable weak interaction (such as surface adsorption) with the carbon atoms, which leads to an unstable doping effect. Furthermore, annealing usually needs to be performed at a high temperature of above 1000° C. in the traditional doping processes to repair lattice damages caused by doping. However, most of the low-dimensional materials cannot withstand such a high temperature, and the high-temperature annealing process also limits the compatibility of the device fabrication process. Therefore, the traditional doping processes are unsuitable for transistors with low-dimensional semiconductor materials as channel materials.

Because of their ultra-thin channel characteristics and limited carrier concentration as compared with bulk semiconductor materials, it is easier for the low-dimensional semiconductor materials to realize electrostatic control such as gate control and electrostatic doping than the bulk semiconductor materials. In order to achieve improvements in terms of threshold voltage and on/off ratio, the local bottom gate process may be used to regulate transistors with the low-dimensional semiconductor materials as channel materials, but in this method, the regulation of the threshold voltage is mainly realized by electrostatically doping a passivation layer on the channel surface. On the one hand, it is difficult for the local bottom gate process to achieve self-alignment, so the source and drain of the fabricated transistor usually overlap with the gate, resulting in larger parasitic capacitance, and poor process repeatability and uniformity. On the other hand, in order to achieve electrostatic doping, the passivation layer on the channel surface is usually made of a metal oxide with a non-ideal atomic ratio, which has an unstable structure and poor thermal stability, so the passivation layer is susceptible to changes or interface reactions in the subsequent processes, resulting in the change of electrostatic doping, thereby causing uncontrollable changes of the transistor’s performances.

In summary, if effective electrostatic doping techniques based on the low-dimensional semiconductor materials can be developed to enable the key indicators like the threshold voltage of transistors to be effectively adjusted, so as to meet the requirements of different modules of integrated circuits for different threshold voltages of transistors, and at the same time, the process can meet the requirements of large-scale production, the advantages of low-dimensional material transistors will be effectively exploited, and the application of low-dimensional semiconductor material transistors will be enlarged.

In view of above, in a first aspect of the present disclosure, a transistor is provided. The transistor includes a substrate, a low-dimensional material layer, a source, a drain, a gate, a gate dielectric layer and spacers. The low-dimensional material layer is provided above the substrate. The source is located at a first side of the gate, and the drain is located at a second side of the gate. The gate dielectric layer is provided between the gate and the low-dimensional material layer. The spacers are provided between the source and the gate and between the drain and the gate, respectively. The substrate has fixed charges, or interface dipoles are formed by the substrate and an insulating dielectric layer, and the insulating dielectric layer includes at least one of the gate dielectric layer and the spacers.

In the transistor according to embodiments of the present disclosure, the low-dimensional material layer may be electrostatically doped in various ways, which have low cost and are better compatible with the fabricating process of the transistor. The low-dimensional semiconductor materials represented by carbon nanotubes have ultra-thin channel characteristics and limited carrier concentration, and are easily regulated through electrostatic control, so through the selection of substrate materials and pretreatment of the substrate, the channel can be electrostatically doped by the fixed charges in the substrate, the dipoles formed at an interface of the substrate and each of the spacers, or the dipoles formed at an interface of the substrate and the gate dielectric layer, thereby realizing the regulation of the threshold voltage and on/off state of the transistor, without affecting the self-alignment top gate process of the transistor. Moreover, when the transistor is used in an integrated circuit, by using different substrate materials in respective functional module regions or performing different substrate pretreatments in the fabricating process of the transistor, different threshold voltages may be achieved in transistors of different functional modules, thereby meeting different requirements of different modules or units for drive capability and power consumption. By adjusting the substrate materials or performing surface pretreatment of the substrate, the threshold voltage and on/off state of the transistor may be regulated, so it is unnecessary to adjust the fabricating process of the transistor too much, thereby greatly reducing the process complexity, saving costs, and improving the yield.

In some embodiments, a material for the low-dimensional material layer includes at least one selected from carbon nanotubes, silicon nanowires, nanowires of elements of groups II-VI, nanowires of elements of groups III-V, and two-dimensional layered semiconductor materials. Therefore, the performance of the transistor may be further improved.

In some embodiments, the substrate has the fixed charges. Optionally, a material for the substrate includes at least one selected from silicon nitride, hafnium oxide and aluminium oxide. Therefore, the low-dimensional material layer may be electrostatically doped by the fixed charges in the substrate.

In some embodiments, the interface dipoles are formed by the substrate and the insulating dielectric layer. Optionally, a material for the substrate includes at least one selected from hafnium oxide, silicon oxide, aluminium oxide and yttrium oxide, and a material for the insulating dielectric layer includes at least one selected from yttrium oxide, zirconium oxide, silicon oxide, hafnium oxide, and aluminium oxide. Therefore, the low-dimensional material layer may be electrostatically doped by the interface dipoles, and thus the threshold voltage and on/off state of the transistor may be adjusted.

In some embodiments, the gate dielectric layer is provided between the low-dimensional material layer and each of the spacers, and the interface dipoles are formed by the gate dielectric layer and the substrate. Therefore, the electrostatic doping of the low-dimensional material layer may be realized, and thus the threshold voltage and on/off state of the transistor may be adjusted.

In some embodiments, the spacers are in contact with the low-dimensional material layer, and the interface dipoles are formed at an interface of the substrate and each of the spacers. Therefore, the electrostatic doping of the low-dimensional material layer may be realized, and thus the threshold voltage and on/off state of the transistor may be adjusted.

In some embodiments, the interface dipoles are formed by the gate dielectric layer and the substrate and by each of the spacers and the substrate, and a direction of a dipole moment of the interface dipoles formed by the gate dielectric layer and the substrate is the same as or different from that of the interface dipoles formed by each of the spacers and the substrate. Therefore, the low-dimensional material layer may be electrostatically doped by the interface dipoles at the interface of the gate dielectric layer and the substrate and at the interface of each of the spacers and the substrate, respectively, and thus the threshold voltage and on/off state of the transistor may be adjusted.

In some embodiments, a material for the spacers includes a low-K dielectric, thereby reducing a parasitic capacitance between the source and the gate and between the drain and the gate, so as to further improve the performance of the transistor.

In some embodiments, the material for the spacers includes at least one selected from silicon oxide, silicon nitride, silicon oxynitride, aluminium nitride and molybdenum oxide. Therefore, the performance of the transistor may be further improved.

In some embodiments, a material for the gate dielectric layer includes a high-K dielectric, preferably yttrium oxide. Therefore, the performance of the transistor may be further improved.

In some embodiments, the transistor further includes a dielectric layer on a surface of the gate away from the gate dielectric layer, and a ratio of a thickness of the dielectric layer to a thickness of the gate is in a range of 1:1 to 20:1. Therefore, the gate is protected by the dielectric layer in a subsequent process.

In some embodiments, the dielectric layer includes at least one selected from silicon nitride and silicon oxide, and the gate includes at least one selected from tantalum nitride (TaN), titanium nitride (TiN) and polycrystalline silicon. Therefore, the performance of the transistor may be further improved.

In some embodiments, the thickness of the dielectric layer is in a range of 100 to 2000 nm, and the thickness of the gate is in a range of 5 to 100 nm. Therefore, the performance of the transistor may be further improved.

In some embodiments, an orthographic projection of the gate on the substrate is within an orthographic projection of the dielectric layer on the substrate. Therefore, the performance of the transistor may be further improved.

In some embodiments, a ratio of a distance between the source and the gate or between the drain and the gate to a length of a channel is in a range of 0.1 to 0.4, and the length of the channel is in a range of 10 nm to 5 µm. Therefore, the performance of the transistor may be further improved.

In a second aspect of the present disclosure, a method for fabricating the transistor as described hereinbefore is provided. The method includes: forming a low-dimensional material layer, a gate dielectric layer, a source, a drain and a gate above a substrate, in which the gate dielectric layer is located between the low-dimensional material layer and the gate; and forming spacers between the source and the gate and between the drain and the gate, respectively. The substrate has fixed charges, or interface dipoles are formed by the substrate and an insulating dielectric layer, and the insulating dielectric layer includes at least one of the gate dielectric layer and the spacers. Therefore, the transistor as described above may be obtained easily and conveniently.

In some embodiments, the substrate is formed by thermal oxidation, chemical vapor deposition or atomic layer deposition. Therefore, the substrate may be obtained easily and conveniently, and the fixed charges may be introduced on the surface or inside of the substrate in the above process.

In some embodiments, the method further includes subjecting a surface of the substrate to a pretreatment before the low-dimensional material layer is formed, in which the pretreatment includes at least one of plasma treatment, annealing treatment, wet chemical cleaning, and surface molecule modification. Therefore, surface properties (such as dangling bond passivation, hydroxylation, and the like) of the substrate can be easily adjusted, thereby affecting the surface state (surface charge distribution) of the substrate and the dipole properties (dipole strength, and the like) between the substrate and the gate dielectric layer.

In some embodiments, the method includes: sequentially forming the low-dimensional material layer, a gate dielectric material layer and a gate material layer on the substrate; patterning the gate material layer to form the gate and expose a part of the gate dielectric material layer where the gate is not located; forming a spacer material layer on a top and a sidewall of the gate and the exposed part of the gate dielectric material layer by atomic layer deposition or chemical vapor deposition; removing a part of the spacer material layer by dry etching and retaining the spacer material at the sidewall of the gate to form the spacers; and removing the gate dielectric material layer at a side of the spacer away from the gate by etching to form the gate dielectric layer, and depositing a metal to form the source and the drain, respectively. Therefore, the structures like the spacers, the source and the drain may be formed by etching, thereby improving the yield of the transistor formed by the method and enlarging the production scale of the transistor.

### BRIEF DESCRIPTION OF THE DRAWINGS

These and other aspects and advantages of embodiments of the present disclosure will become apparent and more readily appreciated from the following descriptions made with reference to the drawings, in which:

FIG. 1 is a schematic cross-sectional view of a transistor according to an embodiment of the present disclosure;

FIG. 2 is a schematic cross-sectional view of a transistor according to another embodiment of the present disclosure;

FIG. 3 is a schematic cross-sectional view of a transistor according to yet another embodiment of the present disclosure;

FIG. 4 is a schematic cross-sectional view of a transistor according to yet another embodiment of the present disclosure;

FIG. 5 is a schematic cross-sectional view of a transistor according to yet another embodiment of the present disclosure;

FIG. 6 is a schematic cross-sectional view of a transistor according to yet another embodiment of the present disclosure;

FIG. 7 is a flow chart of a method for fabricating a transistor according to an embodiment of the present disclosure;

FIG. 8 is a flow chart of a method for fabricating a transistor according to another embodiment of the present disclosure;

FIG. 9 shows performance test results of transistors according to inventive example 1 and comparative example 1 of the present disclosure; and

FIG. 10 shows performance test results of transistors according to inventive example 2 and comparative example 2 of the present disclosure.

### DETAILED DESCRIPTION

Embodiments of the present disclosure will be described in detail below, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure, and shall not be construed to limit the present disclosure.

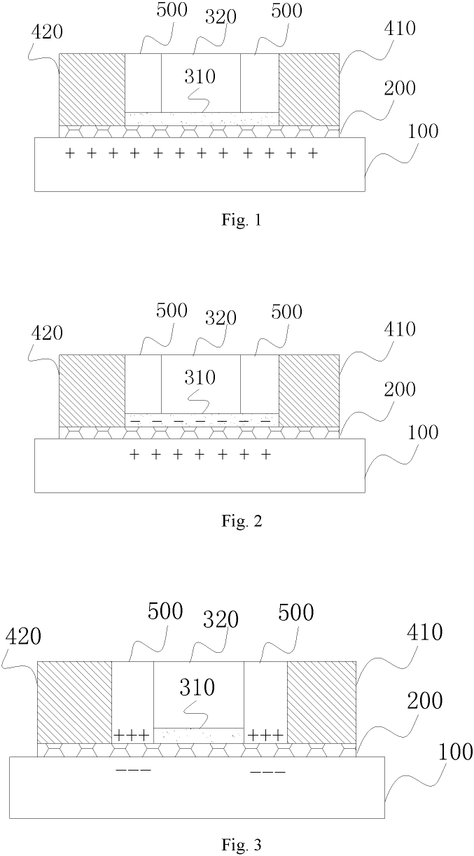

In a first aspect of the present disclosure, a transistor is provided. According to embodiments of the present disclosure, with reference to FIG. 1, the transistor includes a substrate 100, a low-dimensional material layer 200, a source 410, a drain 420, a gate 320, a gate dielectric layer 310 and spacers 500. The substrate 100 has fixed charges. The low-dimensional material layer 200 is provided above the substrate 100 and may be formed from a low-dimensional (one- or two-dimensional) semiconductor material. The source 410 is located at a first side of the gate 320, and the drain 420 is located at a second side of the gate 320. The gate dielectric layer 310 is provided between the gate 320 and the low-dimensional material layer 200. The spacers 500 are provided between the source 410 and the gate 320 and between the drain 420 and the gate 320.

In the transistor according to embodiments of the present disclosure, the low-dimensional material layer may be electrostatically doped in various ways, which alleviates or even eliminates the negative effect of the traditional ion doping process on the transistor with the low-dimensional semiconductor material as the channel material. Further, the electrostatic doping process of the low-dimensional material transistor is compatible with a self-alignment process. Moreover, by flexibly adjusting the fixed charges in the substrate, the dipoles at an interface of the substrate and the gate dielectric layer or the dipoles at an interface of the substrate and each of the spacers, electrical performances (such as the threshold voltage, on/off state, and the like) of the transistor can be effectively regulated, so as to meet different requirements of an integrated circuit for performance parameters (such as the threshold voltage, on/off state, and the like) of transistors in different regions or functional modules, without significantly changing the subsequent fabricating process of the transistor.

For the convenience of understanding, a principle of the transistor for achieving the above advantageous effects is briefly explained as follows.

As mentioned above, it is difficult to apply the traditional doping process to transistors with low-dimensional semiconductor materials as channel materials. Moreover, for transistors with suitable work function metals as contact materials which are fabricated by the self-alignment process with high-K materials as gate dielectrics, for example, the parasitic capacitance between the source and the gate and between the drain and the gate is larger, the threshold voltage is hard to adjust, and the tunneling current in the off state is larger. As to a local bottom gate structure where the electrostatic doping is mainly achieved by a passivation layer on a surface of the channel, it is difficult to ensure the thermal stability and doping effect of the transistor, and the process is complicated. However, in the transistor according to embodiments of the present disclosure, on the one hand, the low-dimensional material layer above the substrate may be electrostatically doped by the fixed charges in the substrate or the interface dipoles formed between the substrate and an insulating dielectric layer, on the other hand, the electrostatic doping by the substrate may be combined with the electrostatic doping by the spacers and the gate stacking. As a result, key performances (such as the threshold voltage, the on/off ratio, and the like) of the transistor can be flexibly regulated, thus facilitating the optimization of the process flow and the reduction of costs. Further, the substrate is located at a bottom of the device and covered by the channel layer, the source, the drain and the top gate layer, so that no interface reaction will occur during the subsequent interconnection process, and the electrostatic doping effect can be guaranteed. In addition, by changing the substrate materials or performing pretreatment of the substrate, the different requirements of the integrated circuit for the threshold voltage of transistors in different modules or units can be met. Specifically, in the fabricating process of the transistor, just by performing different treatments on the substrate materials of the transistors at different positions, the electrostatic doping effects of the low-dimensional material layers of the transistors formed at the respective positions can be separately regulated, without significantly changing the subsequent fabricating process of the transistor, thereby reducing the costs.

In some embodiments, a material for the low-dimensional material layer (i.e., the channel layer) 200 is not particularly restricted, and may include, for example, carbon nanotubes, silicon nanowires, nanowires of elements of groups II-VI, nanowires of elements of groups III-V, and two-dimensional layered semiconductor materials. Specifically, the material for the low-dimensional material layer 200 may include single-walled carbon nanotubes, multi-walled carbon nanotubes, networked carbon nanotubes or carbon nanotube arrays. Alternatively, two-dimensional layered nano-materials including, but not limited to, graphene, molybdenum disulfide, black phosphorus and the like may be used to form the low-dimensional material layer 200. Therefore, the performance of the transistor may be further improved.

In some embodiments, a material for the substrate 100 is not particularly restricted, as long as the fixed charges can be introduced on the surface and/or inside of the substrate 100, or any insulating material that is capable of forming the interface dipoles with the insulating dielectric layer (including the gate dielectric layer 310 and/or spacers 500) can be used to form the substrate 100. For example, the material for the substrate 100 may be silicon nitride, aluminium oxide, hafnium oxide, yttrium oxide or the like. In the deposition process, by adjusting the component ratio, the fixed charges may be easily and conveniently formed in the substrate 100 by the above materials. Alternatively, it is also possible to form the interface dipoles at the interface of the substrate 100 and the insulating dielectric layer (including the gate dielectric layer 310 and/or spacers 500), and the low-dimensional material layer 200 is electrostatically doped by the interface dipoles. Specifically, it is possible that the material for the substrate 100 does not have fixed charges, but during the formation of the insulating dielectric layer, an interface reaction occurs at the interface of the insulating dielectric layer and the substrate 100 to form the interface dipoles there. The insulating dielectric layer may include at least one of the spacers 500 and the gate dielectric layer 310. For example, when the substrate 100 contains oxygen atoms, the oxygen atoms at the surface of the substrate 100 may be redistributed during the formation of the insulating dielectric layer, so as to form the interface dipoles. More specifically, when the substrate 100 is made of hafnium oxide, and the material for the insulating dielectric layer includes yttrium oxide, interface dipoles may be formed by the substrate 100 and the insulating dielectric layer. Alternatively, when the substrate 100 is made of silicon oxide, and the material for the insulating dielectric layer is yttrium oxide, Y—Si—O bonds will be formed at the interface of the substrate 100 and the insulating dielectric layer, thereby forming the interface dipoles.

If the charges are at the surface of the substrate 100, such as trapped surface charges, it will easily cause Coulomb scattering of carriers in the channel, thereby reducing the mobility of the carriers, and damaging the reliability of the device at the same time. For this, it is preferred that the fixed charges are distributed inside the substrate 100, or the dipoles are formed at the interface of the insulating dielectric layer (including the spacers 500 and/or the gate dielectric layer 310) and the substrate 100, such that the channel layer may be electrostatically doped by the fixed charges inside the substrate 100 or the dipoles at the interface of the insulating dielectric layer and the substrate 100, without the occurrence of the above problems.

It should be noted that the polarity of the fixed charges (positive or negative charges) in the substrate as well as the polarity distribution of charges of the dipoles at the interface of the substrate 100 and the insulating dielectric layer (including the gate dielectric layer 310 and/or spacers 500) shown in the drawings of the present disclosure are only for convenience of description, and shall not be construed to limit the polarity and polarity distribution of the charges. Specifically, in the present disclosure, the charges inside the substrate 100 or at the interface of the substrate 100 and the insulating dielectric layer may be positive charges or negative charges.

In some embodiments, a material for the gate dielectric layer 310 is also not particularly restricted, which may be selected as required. For example, the gate dielectric layer 310 may be formed from an electrically insulating material commonly used in the transistor. According to some specific embodiments of the present disclosure, the material for the gate dielectric layer 310 may include a high-K dielectric, preferably yttrium oxide. Therefore, the performance of the transistor may be further improved. The inventors have found that, when using yttrium oxide to form the gate dielectric layer 310, the yttrium oxide layer may also be functioned as an etching stop layer in the etching process, so as to prevent the low-dimensional material layer 200 below the gate dielectric layer 310 from being damaged by the etching process. By selecting different materials for the gate dielectric layer, the interface dipoles formed by the gate dielectric layer and the substrate 100 may be controlled.

In some embodiments, referring to FIG. 1 and FIG. 2, the gate dielectric layer 310 may be extended to source and drain regions, i.e., the gate dielectric layer 310 may be located above a channel region between the source side and the drain side, and separate the low-dimensional material layer 200 from the gate 320 and the spacers 500. Therefore, the low-dimensional material layer in the source and drain regions is protected by the gate dielectric layer when the spacers are deposited. Specifically, the gate dielectric layer 310 may be used as a protective layer to avoid damaging the low-dimensional material layer 200 formed from carbon nanotubes, so that the spacer material may be deposited by thermal atomic layer deposition (ALD), plasma enhanced atomic layer deposition (PEALD), plasma enhanced chemical vapor deposition (PECVD), physical vapor deposition and the like. At this time, the above interface dipoles may be formed by the gate dielectric layer 310 and the substrate 100 to electrostatically dope the low-dimensional material layer.

Alternatively, referring to FIG. 3, the gate dielectric layer 310 does not separate the spacers 500 from the low-dimensional material layer 200, and the low-dimensional material layer 200 may be in contact with the spacers 500. In some embodiments, a material for the spacers 500 is not particularly restricted, which may be selected as required. For example, the material for the spacers 500 may include a high-K dielectric, such as aluminium oxide, hafnium oxide, aluminium nitride and the like, or may include a low-K dielectric, such as silicon oxide, silicon nitride, silicon oxynitride and the like. When the spacers 500 are formed from the low-K dielectric, the parasitic capacitance between the source 410 and the gate 320 and between the drain 420 and the gate 320 may be reduced, thereby further improving the performance of the transistor. In some embodiments, the material for the spacers 500 includes a metal oxide, which includes many types and thus provides more selections for the spacers 500. For example, the material for the spacers 500 includes a metal oxide containing nitrogen or silicon. Similarly, the interface dipoles may also be formed by the spacers 500 and the substrate 100, so as to electrostatically dope the low-dimensional material layer 200 below the spacers 500.

In some embodiments, the material for the spacers 500 may include at least one selected from silicon oxide, silicon nitride, silicon oxynitride and molybdenum oxide. According to specific embodiments of the present disclosure, the size of the spacer 500 is not particularly restricted, which may be determined based on the specific requirements of the transistor. By adjusting the size and material of the spacers 500, characteristics of the interface dipoles may be adjusted, and thus the electrostatic doping level of the low-dimensional material layer 200 may be adjusted, thereby realizing the adjustment of the threshold voltage, the on state, the off state, the uniformity and reliability of the transistor. In a preferred embodiment, the spacers 500 are formed from an inorganic material, so that the thermal conductivity, thermal stability and reliability of the transistor are improved by taking advantage of the better thermal conductivity and reliability of the inorganic material.

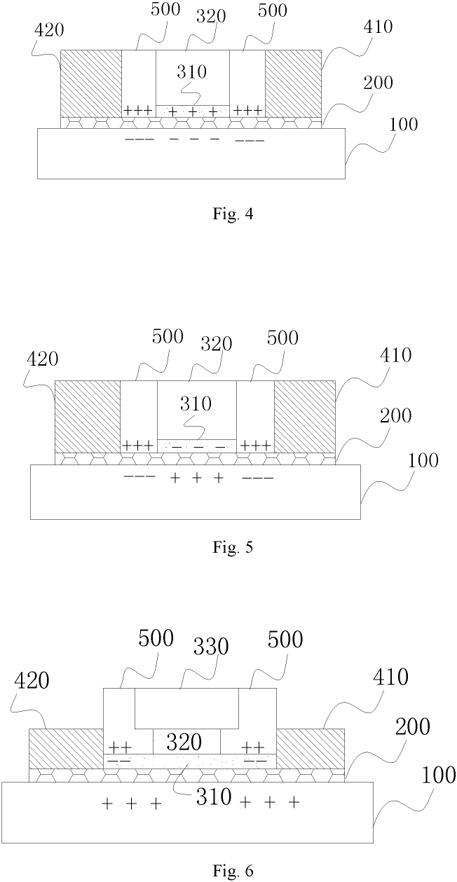

In some embodiments, referring to FIG. 4 and FIG. 5, both the spacers 500 and the gate dielectric layer 310 may form the interface dipoles with the substrate 100, that is, the interface dipoles may be formed between each of the spacers 500 and the substrate 100 and between the gate dielectric layer 310 and the substrate 100, respectively. It will be appreciated that a direction of a dipole moment of the interface dipoles formed by the gate dielectric layer 310 and the substrate 100 may be the same as or different from that of the interface dipoles formed by each of the spacers 500 and the substrate 100, which can be adjusted as required. For example, referring to FIG. 4, the dipole moment of the interface dipoles formed by the gate dielectric layer 310 and the substrate 100 is in the same direction as that of the interface dipoles formed by each of the spacers 500 and the substrate 100. For another example, referring to FIG. 5, the dipole moment of the interface dipoles formed by the gate dielectric layer 310 and the substrate 100 is in an opposite direction to that of the interface dipoles formed by each of the spacers 500 and the substrate 100. Therefore, the regulation manners of the transistor are further enriched.

As described above, in addition to the interface dipoles formed by the substrate 100 and the insulating dielectric layer, the low-dimensional material layer 200 may also be electrostatically doped by the fixed charges in the substrate 100. The fixed charges may be introduced to the substrate 100 in flexible and diversified ways, which include, but are not limited to, controlling the deposition process, controlling the electrical properties and density of the fixed charges in the substrate at different positions. Therefore, the electrostatic doping of the low-dimensional material layer 200 may be achieved flexibly.

In some embodiments, referring to FIG. 6, the transistor may further include a dielectric layer 330 on a surface of the gate 320 away from the gate dielectric layer 310. The dielectric layer 330 may include at least one selected from silicon nitride and silicon oxide. In the etching process for forming structures like the gate 320, the dielectric layer 330 may prevent the gate dielectric layer 310 and the gate 320 therebelow from being affected by etching and play an electrically insulating effect. According to some specific embodiments of the present disclosure, a ratio of a thickness of the dielectric layer 330 to a thickness of the gate 320 is in a range of 1:1 to 20:1. In some specific examples, the thickness of the dielectric layer 330 may be two or more times as large as the thickness of the gate 320. For example, the thickness of the dielectric layer 330 is in a range of 100 to 2000 nm, and the thickness of the gate 320 is in a range of 5 to 100 nm. The thicker dielectric layer 330 may better play the electrically insulating effect and better protect the gate dielectric layer 310 and the gate 320 therebelow in the etching process. Therefore, the performance of the transistor may be further improved.

In some embodiments, referring to FIG. 6, a size of the gate 320 may be smaller than that of the dielectric layer 330, i.e., an orthographic projection of the gate 320 on the substrate 100 is within an orthographic projection of the dielectric layer 330 on the substrate 100. Therefore, the dielectric layer 330 above the gate 320 and the spacers 500 may be used as self-alignment masks to prepare the source 410 and the drain 420, thereby further reducing the parasitic capacitance between the gate 320 and the source 410 and between the gate 320 and the drain 420. A material for the gate 320 may include a metal material, such as tantalum nitride (TaN) and titanium nitride (TiN)), and polycrystalline silicon. Therefore, by adjusting the etching parameters, the gate material layer may be laterally etched easily and conveniently, so as to form the gate 320 with a width smaller than that of the dielectric layer 330.

In some embodiments, a ratio of a distance between the source 410 and the gate 320 or between the drain 420 and the gate 320 (i.e., a size of the spacer region) to a length of the channel is in a range of 0.1 to 0.4, and the length of the channel is in a range of 10 nm to 5 µm. Therefore, by adjusting the size of the spacers 500, parameters like the threshold voltage, the contact resistance and the parasitic capacitance of the transistor are regulated to meet the requirements of the comprehensive indicators of the transistor in practical applications.

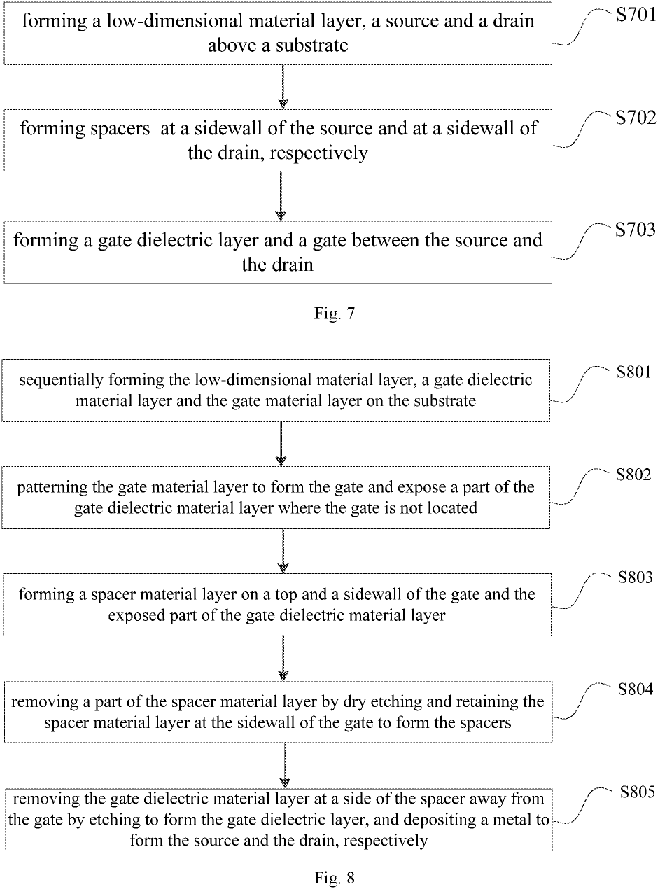

In a second aspect of the present disclosure, a method for fabricating the transistor as described above is provided. Referring to FIG. 7, the method includes the following steps.

In step S701: a low-dimensional material layer, a source and a drain are formed above a substrate.

The respective positions of the low-dimensional material layer, the source and the drain are described in detail hereinbefore, which will not be elaborated here. When fixed charges needs to be introduced into the substrate, the fixed charges may be formed in the substrate before the structures like the low-dimensional material layer 200 are formed.

In some specific embodiments of the present disclosure, a suitable substrate material (including but not limited to silicon oxide (SiO₂), silicon nitride (SiN), silicon oxynitride (SiON) as described above) may be selected, and the fixed charges are introduced into the substrate during its fabrication using the substrate material. For example, the substrate may be a film fabricated by a process including but not limited to chemical vapor deposition, atomic layer deposition or thermal oxidation, and the fixed charges are introduced into the substrate during its fabrication.

In some embodiments, the distribution and density of the fixed charges may be adjusted by fabricating the substrate with the same kind of material (such as silicon nitride (SiN)) through different deposition processes, such as a silicon nitride substrate fabricated by low pressure chemical vapor deposition (LPCVD), a silicon nitride substrate fabricated by PECVD or a silicon nitride substrate fabricated by PEALD.

In some embodiments, prior to the formation of subsequent structures, the substrate may be subjected to a pretreatment including at least one of such as plasma treatment, annealing treatment, wet chemical cleaning and surface molecule modification, so as to adjust surface properties (such as dangling bond passivation, hydroxylation, etc.) and surface states of the substrate, thereby controlling properties like strength of the dipoles formed between the substrate and the gate dielectric layer and between the substrate and each of the spacers.

In step S702: spacers are formed at a sidewall of the source and at a sidewall of the drain, respectively.

In this step, the spacers as described above are formed. Specifically, a protective layer (for example made of yttrium oxide) is deposited above the low-dimensional material layer to prevent the low-dimensional material layer from being damaged in the subsequent deposition and etching processes, then a spacer material layer is deposited on surfaces of the source, the drain and the protective layer by atomic layer deposition or chemical vapor deposition, after which the spacer material on the surface of the protective layer is removed by selective reactive ion etching, and the spacer material at the sidewalls of the source and the drain are retained to form the spacers.

In step S703: a gate dielectric layer and a gate are formed between the source and the drain.

In this step, the gate dielectric layer and the gate are formed above the low-dimensional material layer and between the source and the drain. Specifically, the protective layer above the low-dimensional material layer is removed by non-destructive chemical etching like wet chemical cleaning, and then the gate dielectric layer and the gate are deposited. In this way, the transistor as described above may be fabricated easily and conveniently.

It should be illustrated that the sequence of forming the low-dimensional material layer, the source, the drain, the spacers, the gate dielectric layer, and the gate in this method is not particularly restricted, which may be selected according to the specific structure (as shown in FIG. 1 to FIG. 6) and fabrication process of the transistor.

In some specific embodiments of the present disclosure, the transistor may be formed by an etching process. As compared with a stripping process, the etching process has a better product yield, and can avoid the occurrence of defects such as contamination of the low-dimensional material layer caused by incomplete stripping during large-scale production.

In the following, each step of the method based on the etching process will be described in detail according to specific embodiments of the present disclosure. Specifically, referring to FIG. 8, the method includes the following steps.

In step S801: a low-dimensional material layer, a gate dielectric material layer and a gate material layer are sequentially formed on the substrate.

According to some embodiments of the present disclosure, in this step, the low-dimensional material layer, the gate dielectric material layer and the gate material layer may be sequentially formed by a depositing process.

Specifically, the substrate may be an electrically insulating substrate like a SiO₂/Si substrate, a quartz substrate, an Al₂O₃ substrate or the like.

The low-dimensional material layer may be a carbon nanotube array film, a networked carbon nanotube film, a layer of nanowires (such as silicon nanowires, nanowires of elements of groups II-VI, or nanowires of elements of groups III-V), a two-dimensional semiconductor material layer or the like. The forming manner of the low-dimensional material layer is not particularly restricted. For example, the low-dimensional material layer may be formed on a surface of the substrate by solution deposition or may be transferred to the surface of the substrate by a transfer technique.

The material for the gate dielectric material layer is not particularly restricted, and may be selected correspondingly based on the type of materials in the low-dimensional material layer. Preferably, the material for the gate dielectric material layer is a high-K dielectric. When the low-dimensional material layer is a carbon nanotube film, yttrium oxide (Y₂O₃) or a combination of yttrium oxide (Y₂O₃) and a high-K dielectric other than yttrium oxide may be selected to form the gate dielectric material layer, in which the yttrium oxide layer may also be functioned as an etching stop layer to prevent the carbon nanotubes from being damaged by plasma etching. For example, the gate dielectric material layer, e.g., an yttrium oxide layer, may be formed by atomic layer deposition (ALD), chemical vapor deposition (CVD), plasma enhanced chemical vapor deposition (PECVD), physical vapor deposition (PVD), electron beam evaporation deposition, thermal oxidation or the like. Specifically, an yttrium oxide film may be formed by electron beam evaporation deposition and then performing thermal oxidation. Dipoles may be formed at an interface of the gate dielectric layer and the substrate to electrostatically dope the low-dimensional material layer. In an embodiment, the gate dielectric layer is formed from yttrium oxide, and the substrate is formed from silicon oxide.

The gate material layer may be formed from a metal material (e.g. TaN, TiN or the like) or a compound material (e.g. polycrystalline silicon). For example, the gate material layer may be formed from TaN. The etching process for TaN is relatively mature, and using TaN to form the gate material layer may improve the yield and reduce the process cost. In the subsequent steps, the gate material layer and the gate dielectric material layer are patterned by etching to form the gate and the gate dielectric layer of the transistor, respectively. The gate material layer, e.g., a TaN layer, may be formed by atomic layer deposition, chemical vapor deposition (CVD), plasma enhanced chemical vapor deposition (PECVD), physical vapor deposition (PVD) or electron beam evaporation deposition or the like. For example, the gate material layer may be formed by depositing a layer of TaN using physical vapor deposition.

In some embodiments of the present disclosure, a dielectric material layer may be formed above the gate material layer. For example, the dielectric material layer may be formed from silicon oxide (e.g., SiO₂) or silicon nitride (Si₃N₄), so as to prevent the gate dielectric layer and the gate therebelow from being affected by etching in the subsequent etching process and play an electrically insulating effect. The dielectric material layer may be used as a hard mask in the etching process and as a self-alignment mask in the subsequent formation of the source and the drain. The forming manner of the dielectric material layer, e.g., a silicon oxide or silicon nitride layer, is not particularly restricted. For example, the silicon oxide layer may be formed by plasma enhanced chemical vapor deposition (PECVD).

In step S802: the gate material layer is patterned to form the gate and expose a part of the gate dielectric material layer.

According to embodiments of the present disclosure, in this step, the gate material layer is patterned to form the gate and expose a part of the gate dielectric material layer where the gate is not located. Specifically, an etching mask may be provided above the gate material layer, and a part of the gate material layer outside a gate region is removed.

In some specific embodiments of the present disclosure, when the dielectric material layer is provided above the gate material layer, a mask formed from a photoresist may be provided above the dielectric material layer, a part of the dielectric material layer not covered by the mask is removed by etching to form a dielectric layer, and then the dielectric layer is used as a hard mask, so that a part of the gate material layer outside the gate region is removed by etching to form the gate.

As mentioned above, when yttrium oxide (Y₂O₃) is used to form the gate dielectric material layer, the gate dielectric material layer may be used as an etching stop layer, so as to prevent the low-dimensional material layer from being damaged by etching when forming the gate.

In step S803: a spacer material layer is formed on a top and a sidewall of the gate and the exposed part of the gate dielectric material layer.

According to embodiments of the present disclosure, in this step, the spacer material layer may be formed on the top and sidewall of the gate and the exposed part of the gate dielectric material layer by atomic layer deposition (ALD) or chemical vapor deposition (CVD). Since the gate material layer in a source region and a drain region is removed in the previous step, the spacer material layer deposited in this step may cover the top and sidewalls of the gate (or the dielectric layer) and a surface of the exposed part of the gate dielectric material layer at the source and drain regions. Therefore, the spacers may be formed in contact with the sidewalls of the gate. Afterwards, spacers with their sidewalls being respectively joined with the source and the drain may be obtained by forming the source and the drain at sides of the spacers away from the gate, respectively. In addition, the specific materials of the spacers and the fixed charges contained therein are described in detail above, which will not be elaborated here.

Specifically, by choosing different types of materials for the spacers, the low-dimensional material layer may be electrostatically doped by the spacers in electronic doping or hole doping. For example, by choosing different types of materials for the spacers, the spacers may contain fixed charges therein, or the spacers may form dipoles with the substrate or with the gate dielectric layer.

In step S804: a part of the spacer material layer is removed by dry etching and the spacer material layer at the sidewalls of the gate is retained to form the spacers.

According to embodiments of the present disclosure, in this step, a part of the spacer material layer is removed by dry etching and a remaining part of the spacer material layer at the sidewalls of the gate is retained to form the spacers. For example, a part of the spacer material layer which covers the regions for forming the source and the drain, and/or a part of the spacer material layer located at a top of the dielectric layer may be removed. The specific process parameters of dry etching are not particularly restricted, which may be controlled according to specific types of the spacer materials.

In step S805: the gate dielectric material layer at a side of the spacer away from the gate is removed by etching to form the gate dielectric layer, and the source and the drain are formed, respectively.

According to embodiments of the present disclosure, in this step, a part of the gate dielectric material layer which covers the regions for forming the source and the drain may be removed, and a metal material layer is deposited to form the source and the drain. Specifically, a metal material layer for the source and the drain may be deposited, and then a part of the metal material layer outside the source and drain regions is removed by etching, so as to form the source and the drain, respectively. Therefore, the gate, the spacers, the source, the drain and the like may be formed based on the etching process, which improves the yield of the transistor and realizes the large-scale production of the transistor. Specifically, when the gate dielectric material layer is formed from yttrium oxide (Y₂O₃), the gate dielectric layer may be formed by removing yttrium oxide (Y₂O₃) by wet etching with an etchant at an etching temperature of 0 to 30° C. The etchant includes diluted hydrochloric acid. Specifically, the etchant may be an aqueous solution formed by diluting 37% concentrated hydrochloric acid with water in a ratio of hydrochloric acid to water ranging from 1:20 to 1:100. When the gate dielectric material layer includes yttrium oxide and a high-K dielectric other than yttrium oxide, the high-K dielectric other than yttrium oxide may be removed by dry etching, and yttrium oxide may be removed by the wet etching as descried above. In this way, the gate dielectric layer is formed.

In some embodiments of the present disclosure, the transistor as shown in FIG. 6 may be fabricated by adjusting the specific parameters of the etching process. In specific embodiments of the present disclosure, the dielectric material layer may be formed from silicon nitride or silicon oxide, and the gate material layer may be formed from tantalum nitride. The dielectric layer and the gate may be formed by reactive ion etching or inductively coupled plasma etching. Specifically, the etching parameters are adjusted to perform longitudinal etching on the dielectric material layer and the gate material layer, and then the etching parameters are readjusted to perform lateral etching on the gate material layer. As a result, a lateral width of the gate thus formed is less than that of the dielectric layer.

Specifically, the dielectric material layer and the gate material layer may be longitudinally etched by reactive ion etching using a longitudinal etching gas, in which the longitudinal etching gas includes trifluoromethane and argon, and a volume percentage of trifluoromethane in the longitudinal etching gas is in a range of 30% to 95%. Alternatively, the dielectric material layer is longitudinally etched by inductively coupled plasma etching, in which a power of a bottom electrode is greater than 10% of a power of a top electrode.

Subsequently, the lateral etching is performed. Specifically, the gate material layer may be laterally etched by reactive ion etching using a lateral etching gas, in which the lateral etching gas includes sulfur hexafluoride and argon, and a volume percentage of sulfur hexafluoride in the lateral etching gas is in a range of 30% to 95%. Alternatively, the gate material layer is laterally etched by inductively coupled plasma etching, in which a power of a bottom electrode is less than 15% of a power of a top electrode. Therefore, a structure in which a width of the dielectric layer is greater than that of the gate may be formed.

In the specification of the present disclosure, the terms “upper”, “lower”, etc. should be construed to refer to the orientation or positional relationship as then described or as shown in the drawings under discussion. These relative terms are for convenience of description and do not require that the present disclosure be constructed or operated in a particular orientation.

In the specification of the present disclosure, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

### Inventive Example 1

In this example, a P-type transistor (PMOS) with a structure as shown in FIG. 2 is fabricated. Specifically, in this P-type transistor (PMOS), the low-dimensional material layer is formed from carbon nanotubes, both the source and the drain are formed from Pd, the spacers are formed from silicon oxide (SiO₂), the gate dielectric layer is formed from yttrium oxide (Y₂O₃), and the substrate is formed form silicon oxide.

### Comparative Example 1

In this example, except that the substrate is formed form yttrium oxide, other parameters are the same as Inventive Example 1.

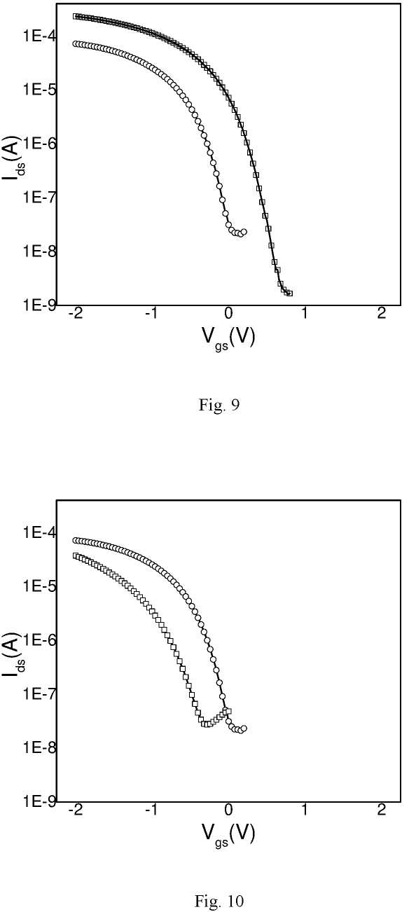

Performances of the transistors obtained in Inventive Example 1 and Comparative example 1 are tested. Referring to FIG. 9, as compared with the transistor (represented by hollow circles) where the substrate is formed from yttrium oxide, in the transistor (represented by hollow squares) where the substrate is formed from silicon oxide, the channel formed from carbon nanotubes is electrostatically doped (in hole doping manner) by dipoles formed between the yttrium oxide gate dielectric layer and the silicon oxide substrate, the threshold voltage of the transistor is shifted to the right relatively, the reverse tunneling in the off state is effectively inhibited, so that the current in the off state is smaller.

### Inventive Example 2

In this example, a P-type transistor (PMOS) with a structure as shown in FIG. 1 is fabricated. Specifically, in this P-type transistor (PMOS), the low-dimensional material layer is formed from carbon nanotubes, both the source and the drain are formed from Pd, the spacers are formed from silicon oxide (SiO₂), the gate dielectric layer is formed from yttrium oxide (Y₂O₃), and the substrate is formed form silicon nitride (SiN).

### Comparative Example 2

In this example, except that the substrate is formed form yttrium oxide, other parameters are the same as Inventive Example 2.

Performances of the transistors obtained in Inventive Example 2 and Comparative example 2 are tested. Referring to FIG. 10, in the transistor (represented by hollow squares) where the substrate is formed from silicon nitride, as the channel formed from carbon nanotubes is electronically doped by fixed positive charges contained in the silicon nitride substrate, the threshold voltage of this transistor is shifted to the lift relatively as compared with the transistor (represented by hollow circles) where the substrate is formed from yttrium oxide.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples. Although explanatory embodiments have been shown and described, it would be appreciated by those skilled in the art that changes, alternatives, and modifications may be made in the embodiments without departing from spirit and principles of the disclosure. In addition, it should be noted that terms such as “first” and “second” are used herein for purposes of description and are not intended to indicate or imply relative importance or significance.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

1. A transistor, comprising:
a substrate;
a low-dimensional material layer provided above the substrate;
a gate;
a source, located at a first side of the gate;
a drain, located at a second side of the gate;
a gate dielectric layer provided between the gate and the low-dimensional material layer; and
spacers, provided between the source and the gate and between the drain and the gate, respectively,
wherein the substrate has fixed charges, or interface dipoles are formed by the substrate and an insulating dielectric layer comprising at least one of the gate dielectric layer and the spacers.

2. The transistor according to claim 1, wherein a material for the low-dimensional material layer comprises at least one selected from carbon nanotubes, silicon nanowires, nanowires of elements of groups II-VI, nanowires of elements of groups III-V, and two-dimensional layered semiconductor materials.

3. The transistor according to claim 1, wherein the substrate has the fixed charges, and a material for the substrate comprises at least one selected from silicon nitride, hafnium oxide and aluminum oxide.

4. The transistor according to claim 1, wherein the interface dipoles are formed by the substrate and the insulating dielectric layer, wherein a material for the substrate comprises at least one selected from hafnium oxide, silicon oxide, aluminum oxide, and yttrium oxide, and wherein a material for the insulating dielectric layer comprises at least one selected from yttrium oxide, zirconium oxide, silicon oxide, hafnium oxide, and aluminum oxide.

5. The transistor according to claim 1, wherein the gate dielectric layer is provided between the low-dimensional material layer and each of the spacers, and the interface dipoles are formed by the gate dielectric layer and the substrate.

6. The transistor according to claim 1, wherein the spacers are in contact with the low-dimensional material layer, and the interface dipoles are formed at an interface of the substrate and each of the spacers.

7. The transistor according to claim 1, wherein the interface dipoles are formed by the gate dielectric layer and the substrate and by each of the spacers and the substrate, and a direction of a dipole moment of the interface dipoles formed by the gate dielectric layer and the substrate is the same as or different from that of the interface dipoles formed by each of the spacers and the substrate.

8. The transistor according to claim 1, wherein:
a material for the spacers comprises a low-K dielectric, comprising at least one selected from silicon oxide, silicon nitride, silicon oxynitride, aluminum nitride and molybdenum oxide; and
a material for the gate dielectric layer comprises a high-K dielectric, comprising yttrium oxide.

9. The transistor according to claim 1, further comprising a second dielectric layer on a surface of the gate away from the gate dielectric layer, wherein:
a ratio of a thickness of the second dielectric layer to a thickness of the gate is in a range of 1:1 to 20:1;
the second dielectric layer comprises at least one selected from silicon nitride and silicon oxide, and the gate comprises at least one selected from tantalum nitride (TaN), titanium nitride (TiN) and polycrystalline silicon;
the thickness of the second dielectric layer is in a range of 100 to 2000 nm; and/or
the thickness of the gate is in a range of 5 to 100 nm.

10. The transistor according to claim 9, wherein an orthographic projection of the gate on the substrate is within an orthographic projection of the second dielectric layer on the substrate;
a ratio of a distance between the source and the gate or between the drain and the gate to a length of a channel is in a range of 0.1 to 0.4; and/or
the length of the channel is in a range of 10 nm to 5 µm.

11. A method for fabricating a transistor, comprising:
forming a low-dimensional material layer, a gate dielectric layer, a source, a drain and a gate above a substrate, wherein the gate dielectric layer is located between the low-dimensional material layer and the gate; and
forming spacers between the source and the gate and between the drain and the gate, respectively;
wherein the substrate has fixed charges, or interface dipoles are formed by the substrate and an insulating dielectric layer comprising at least one of the gate dielectric layer and the spacers.

12. The method according to claim 11, further comprising:
forming the substrate by thermal oxidation, chemical vapor deposition, physical vapor deposition or atomic layer deposition; and/or
subjecting a surface of the substrate to a pretreatment before the low-dimensional material layer is formed, wherein the pretreatment comprises at least one of plasma treatment, annealing treatment, wet chemical cleaning, and surface molecule modification.

13. The method according to claim 11, comprising:
sequentially forming the low-dimensional material layer, a gate dielectric material layer and a gate material layer on the substrate;
patterning the gate material layer to form the gate and expose a part of the gate dielectric material layer where the gate is not located;
forming a spacer material layer on a top and a sidewall of the gate and the exposed part of the gate dielectric material layer by atomic layer deposition or chemical vapor deposition;
removing a part of the spacer material layer by dry etching and retaining the spacer material layer at the sidewall of the gate to form the spacers;
removing the gate dielectric material layer at a side of the spacers away from the gate by etching to form the gate dielectric layer; and
depositing a metal to form the source and the drain, respectively.
